(19) United States
(12) Patent Application Publication
(10) Pub. No.: US 2026/0304634 A1
(43) Pub. Date: Oct. 1, 2026

(54) WIRING BOARD

(71) Applicant: SHINKO ELECTRIC INDUSTRIES CO., LTD., Nagano (JP)

(72) Inventor: Hiroya OKAMOTO, Nagano (JP)

(21) Appl. No.: 19/574,982

(22) Filed: Mar. 23, 2026

(30) Foreign Application Priority Data
Mar. 26, 2025 (JP) 2025-052408

(51) Int. Cl. H05K 1/185; H05K 1/11; H05K 3/34

(52) U.S. Cl. CPC H05K 1/185; H05K 1/113; H05K 3/34; H05K 2201/09036; H05K 2201/10515

(57) ABSTRACT

A wiring board includes an interconnect layer including a pad, a first insulating layer formed on the interconnect layer, a barrier interconnect formed on the first insulating layer and surrounding the pad in a plan view, a second insulating layer formed on the first insulating layer and covering at least an outer periphery of an upper surface of the barrier interconnect, and a cavity penetrating the second insulating layer and the first insulating layer and exposing an upper surface of the pad, wherein a bottom surface of the cavity is located inside an inner surface of the barrier interconnect in the plan view.

### CROSS-REFERENCE TO RELATED APPLICATIONS

This application is based upon and claims priority to Japanese Patent Application No. 2025-052408, filed on Mar. 26, 2025, the entire contents of which are incorporated herein by reference.

### FIELD

Certain aspects of the embodiments discussed herein are related to wiring boards, and methods for manufacturing wiring boards.

### BACKGROUND

There is a known wiring board having an electronic component disposed inside a cavity. In order to form the cavity of such a wiring board, a stack including a plurality of insulating layers and a plurality of interconnect layers is first formed, for example. The plurality of interconnect layers include a barrier interconnect that serves as an etching barrier during etching, and a pad that is located below the barrier interconnect and is connected to the electronic component. Next, a mask having an opening for forming the cavity is disposed on the uppermost insulating layer constituting the stack, and a blasting process is performed until the barrier interconnect is exposed through the mask. Next, after the barrier interconnect is completely removed, etching is performed until the pad is exposed. As a result, the cavity in which the electronic component can be disposed is formed, and the pad connectable to the electronic component is exposed inside the cavity.

Examples of the related art include U.S. Pat. No. 11,382,213, for example.

In the method for forming the cavity described above, the position of the opening is determined with reference to an alignment mark provided near the uppermost insulating layer in order to form the opening in the mask. However, because a plurality of layers are provided between the barrier interconnect and the uppermost insulating layer, it is difficult to accurately align the position of the opening with the position of the barrier interconnect. When the position of the opening deviates from the position of the barrier interconnect, the position where the cavity is formed also deviates, and thus, an insulating layer that should not be removed may be removed, and an interconnect that should be covered with the insulating layer may become exposed inside the cavity.

### SUMMARY

It is an object in one aspect of the embodiments of the present disclosure to provide a wiring board capable of reducing a defect caused by a positional deviation that occurs when forming a cavity in which an electronic component is to be disposed.

According to one aspect of the embodiments of the present disclosure, a wiring board includes an interconnect layer including a pad; a first insulating layer formed on the interconnect layer; a barrier interconnect formed on the first insulating layer and surrounding the pad in a plan view; a second insulating layer formed on the first insulating layer and covering at least an outer periphery of an upper surface of the barrier interconnect; and a cavity penetrating the second insulating layer and the first insulating layer and exposing an upper surface of the pad, wherein a bottom surface of the cavity is located inside an inner surface of the barrier interconnect in the plan view.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view illustrating an example of a wiring board according to a first embodiment;

FIG. 2A, FIG. 2B, FIG. 2C, and FIG. 2D are diagrams illustrating examples of manufacturing processes of the wiring board according to the first embodiment;

FIG. 3A, FIG. 3B, and FIG. 3C are diagrams illustrating examples of manufacturing processes of the wiring board according to the first embodiment;

FIG. 4A, FIG. 4B, and FIG. 4C are diagrams illustrating examples of manufacturing processes of the wiring board according to the first embodiment;

FIG. 5 is a cross sectional view illustrating an example of the wiring board according to a first modification of the first embodiment;

FIG. 6 is a cross sectional view illustrating an example of the wiring board according to a second modification of the first embodiment;

FIG. 7 is a cross sectional view illustrating an example of the wiring board according to a third modification of the first embodiment;

FIG. 8 is a cross sectional view illustrating an example of the wiring board according to a fourth modification of the first embodiment; and

FIG. 9 is a cross sectional view illustrating an example of a semiconductor device according to an application example of the first embodiment.

### DESCRIPTION OF EMBODIMENTS

Hereinafter, embodiments of the present disclosure will be described with reference to the drawings. In the drawings, the same constituent elements or components are designated by the same reference numerals, and a redundant description thereof may be omitted.

### First Embodiment

### [Configuration of Wiring Board]

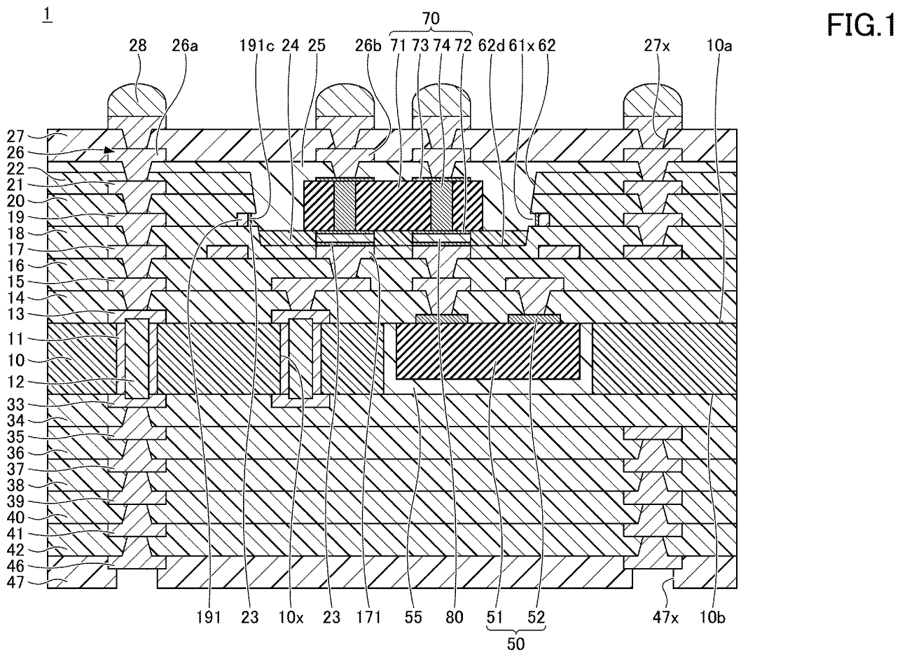

FIG. 1 is a cross sectional view illustrating an example of a wiring board according to a first embodiment. As illustrated in FIG. 1, a wiring board 1 includes interconnect layers and insulating layers stacked on both surfaces of a core layer 10.

Specifically, in the wiring board 1, an interconnect layer 13, an insulating layer 14, an interconnect layer 15, an insulating layer 16, an interconnect layer 17, an insulating layer 18, an interconnect layer 19, an insulating layer 20, an interconnect layer 21, insulating layers 22 and 25, an interconnect layer 26, and a solder resist layer 27 are sequentially stacked on an upper surface 10a of the core layer 10. In addition, an interconnect layer 33, an insulating layer 34, an interconnect layer 35, an insulating layer 36, an interconnect layer 37, an insulating layer 38, an interconnect layer 39, an insulating layer 40, an interconnect layer 41, an insulating layer 42, an interconnect layer 46, and a solder resist layer 47 are sequentially stacked on a lower surface 10b of the core layer 10. The number of the interconnect layers and the number of insulating layers stacked on the upper surface 10a and the lower surface 10b of the core layer 10 are not limited to those of the example illustrated in FIG. 1.

For the sake of convenience, in the first embodiment, the side of the wiring board 1 provided with the solder resist layer 27 will be referred to as an upper side or one side, and the side of the wiring board 1 provided with the solder resist layer 47 will be referred to as a lower side or the other side. Moreover, a surface of each portion on the side of the wiring board 1 provided with the solder resist layer 27 will be referred to as one surface or an upper surface, and a surface of each portion on the side of the wiring board 1 provided with the solder resist layer 47 will be referred to as the other surface or a lower surface. However, the wiring board 1 may be used in an upside-down state or may be disposed at an arbitrary angle. Further, a plan view refers to a view of an object viewed in a normal direction with respect to the upper surface 10a of the core layer 10, and a planar shape refers to a shape of the object in the plan view viewed in the normal direction with respect to the upper surface 10a of the core layer 10.

A so-called glass epoxy substrate or the like having a glass cloth impregnated with an insulating resin, such as an epoxy-based resin or the like, can be used for the core layer 10, for example. A substrate or the like having a woven fabric or a nonwoven fabric of glass fiber, carbon fiber, aramid fiber, or the like impregnated with an epoxy-based resin or the like may be used for the core layer 10. A thickness of the core layer 10 is in a range of approximately 60 μm to 1600 μm, for example. The core layer 10 is provided with through holes 10x penetrating the core layer 10 in a thickness direction. The planar shape of the through hole 10x is a circular shape, for example.

In the illustrated example, an electronic component 50 is embedded in the core layer 10, and a side surface and a lower surface of the electronic component 50 are covered with an insulating resin 55. The electronic component 50 includes a main body 51 and electrodes 52 formed on an electrode forming surface of the main body 51. The electronic component 50 is embedded in the core layer 10 face-up, with the electrodes 52 facing the insulating layer 14. The electronic component 50 may be a passive component or an active component. The electronic component 50 is an integrated passive device (IPD), a semiconductor chip, a silicon bridge, a capacitor, an inductor, a resistor, or the like, for example. The wiring board 1 does not necessarily have to include the electronic component 50.

The interconnect layer 13 is formed on the upper surface 10a of the core layer 10. The interconnect layer 33 is formed on the lower surface 10b of the core layer 10. The interconnect layer 13 and the interconnect layer 33 are electrically connected via through-core vias 11 formed inside the through holes 10x. In the illustrated example, a resin body 12 fills a center portion of the through-core via 11. The resin body 12 has a cylindrical shape, for example, and has an upper end portion protruding into the interconnect layer 13 and a lower end portion protruding into the interconnect layer 33. The through-core via 11 does not necessarily have to include the resin body 12. In this case, an entirety of the through hole 10x is filled with the through-core via 11.

The interconnect layers 13 and 33 are patterned into predetermined planar shapes. The interconnect layers 13 and 33 and the through-core vias 11 may be made of copper (Cu) or the like, for example. Thicknesses of the interconnect layers 13 and 33 are in a range of approximately 10 μm to approximately 50 μm, for example. The interconnect layer 13, the interconnect layer 33, and the through-core vias 11 may be integrally formed.

The insulating layer 14 is formed on the upper surface 10a of the core layer 10 and covers the interconnect layer 13, an upper surface of the electronic component 50, the electrodes 52, and an upper surface of the insulating resin 55. A material used for the insulating layer 14 may be an insulating resin including an epoxy-based resin or a polyimide-based resin as a main component, for example. A thickness of the insulating layer 14 may be in a range of approximately 10 μm to approximately 70 μm, for example. The insulating layer 14 may include a filler, such as silica (SiO₂) or the like.

The interconnect layer 15 is formed on one side of the insulating layer 14. The interconnect layer 15 includes via interconnects penetrating the insulating layer 14, and interconnect patterns and/or pads formed on an upper surface of the insulating layer 14. Some of the interconnect patterns and/or the pads are electrically connected to the interconnect layer 13 through the via interconnects. Some of the interconnect patterns and/or the pads are electrically connected to the electrodes 52 of the electronic component 50 through the via interconnects. A material used for the interconnect layer 15 and a thickness of the interconnect patterns or the like may be the same as those of the interconnect layer 13, for example.

The insulating layer 16 is formed on the upper surface of the insulating layer 14 to cover the interconnect layer 15. A material used for and a thickness of the insulating layer 16 may be the same as those of the insulating layer 14, for example. The insulating layer 16 may include a filler, such as silica (SiO₂) or the like.

The interconnect layer 17 is formed on one side of the insulating layer 16. The interconnect layer 17 includes via interconnects penetrating the insulating layer 16, interconnect patterns formed on an upper surface of the insulating layer 16, and pads 171 formed on the upper surface of the insulating layer 16. The pads 171 are electrically connected to the interconnect layer 15 through the via interconnects. A material used for the interconnect layer 17 and a thickness of the interconnect patterns or the like may be the same as those of the interconnect layer 13, for example. An upper surface of the pad 171 has a circular shape, for example. In this case, a diameter of the upper surface of the pad 171 may be 10 μm or greater and 500 μm or less, for example.

The insulating layer 18 is formed on the upper surface of the insulating layer 16 to cover the interconnect layer 17. A material used for and a thickness of the insulating layer 18 may be the same as those of the insulating layer 14, for example. The insulating layer 18 may include a filler. such as silica (SiO₂) or the like.

The interconnect layer 19 is formed on one side of the insulating layer 18. The interconnect layer 19 includes via interconnects penetrating the insulating layer 18, interconnect patterns and/or pads formed on an upper surface of the insulating layer 18, and a barrier interconnect 191 formed on the upper surface of the insulating layer 18. The interconnect patterns and/or the pads are electrically connected to the interconnect layer 17 through the via interconnects. The barrier interconnect 191 does not necessarily have to be connected to other interconnect patterns and pads. The barrier interconnect 191 surrounds the pads 171 in the plan view. The barrier interconnect 191 can be formed in a picture-frame shape, for example. A material used for the interconnect layer 19 and a thickness of the interconnect patterns or the like may be the same as those of the interconnect layer 13, for example.

The insulating layer 20 is formed on the upper surface of the insulating layer 18 to cover the interconnect layer 19. The insulating layer 20 covers at least an outer periphery of the upper surface of the barrier interconnect 191. The insulating layer 20 may cover the entire upper surface of the barrier interconnect 191. A material used for and a thickness of the insulating layer 20 may be the same as those of the insulating layer 14, for example. The insulating layer 20 may include a filler, such as silica (SiO₂) or the like.

The interconnect layer 21 is formed on one side of the insulating layer 20. The interconnect layer 21 includes via interconnects penetrating the insulating layer 20, and interconnect patterns and/or pads formed on an upper surface of the insulating layer 20. The interconnect patterns and/or the pads are electrically connected to the interconnect layer 19 through the via interconnects. A material used for the interconnect layer 21 and a thickness of the interconnect patterns or the like may be the same as those of the interconnect layer 13, for example.

The insulating layer 22 is formed on the upper surface of the insulating layer 20 to cover the interconnect layer 21. A material used for and a thickness of the insulating layer 22 may be the same as those of the insulating layer 14, for example. The insulating layer 22 may include a filler, such as silica (SiO₂) or the like.

The wiring board 1 has a cavity 62 that penetrates the insulating layer 22, the insulating layer 20, and the insulating layer 18, to expose the upper surfaces of the pads 171. A bottom surface 62d of the cavity 62 is formed by the insulating layer 18. The planar shape of the bottom surface 62d of the cavity 62 can be appropriately determined according to the planar shape of the electronic component to be embedded, and is a rectangular shape, for example. The bottom surface 62d of the cavity 62 is located inside an inner surface 191c of the barrier interconnect 191 in the plan view. In the plan view, an outer edge of the bottom surface 62d of the cavity 62 may match the inner surface 191c of the barrier interconnect 191 in the plan view.

In the illustrated example, the bottom surface 62d of the cavity 62 and the upper surfaces of the pads 171 lie on a single plane. That is, the upper surfaces of the pads 171 are located inside the cavity 62, but side surfaces of the pads 171 are not located inside the cavity 62. The side surfaces of the pads 171 are completely covered with the insulating layer 18. The inner surface of the cavity 62 may be perpendicular to the bottom surface 62d, or may be inclined so that a width of the cavity 62 narrows toward the bottom surface 62d.

The cavity 62 widens from a height position of the barrier interconnect 191. Specifically, a recess 61x formed in the insulating layer 20 has a picture-frame shape in the plan view. The recess 61x has a bottom surface formed by the insulating layer 18, a top surface formed by the insulating layer 20, and a side surface formed by the inner surface 191c of the barrier interconnect 191. That is, the inner surface 191c of the barrier interconnect 191 is located inside the cavity 62. In addition, in the plan view, the barrier interconnect 191 having the picture-frame shape is located outside the recess 61x.

The surfaces of the pads 171 and the barrier interconnect 191 located inside the cavity 62 may be covered with the metal layer 23. In the illustrated example, the upper surfaces of the pads 171 and the inner surface 191c of the barrier interconnect 191 are covered with the metal layer 23. Examples of the metal layer include a gold (Au) layer, a nickel/gold (Ni/Au) layer (a metal layer in which an Ni layer and an Au layer are stacked in this order), a nickel/palladium/gold (Ni/Pd/Au) layer (a metal layer in which an Ni layer, a Pd layer, and a Au layer are stacked in this order), a tin (Sn) layer, or the like. The surfaces of the pads 171 and the barrier interconnect 191 located inside the cavity 62 do not necessarily have to be covered with the metal layer 23.

The wiring board 1 includes an electronic component 70 disposed inside the cavity 62. The electronic component 70 includes a main body 71, first electrodes 72 located on a lower surface side of the main body 71, and second electrodes 73 located on an upper surface side of the main body 71 and electrically connected to the first electrodes 72. In the illustrated example, the first electrodes 72 and the second electrodes 73 are electrically connected through via interconnects 74 penetrating the main body 71, but the electrical connection between the first electrodes 72 and the second electrodes 73 is not limited to the electrical connection using the via interconnects 74. For example, the first electrodes 72 and the second electrodes 73 may be electrically connected via interconnects provided on side surfaces of the main body 71.

The first electrodes 72 of the electronic component 70 are electrically connected to the pads 171 via a conductive bonding material 80 and the metal layer 23. The second electrodes 73 are electrically connected to external connection terminals 28 via the interconnect layer 26. The conductive bonding material 80 is solder, for example. An alloy including Pb, an alloy including Sn and Cu, an alloy including Sn and Ag, an alloy including Sn, Ag, and Cu, or the like can be used for the solder material, for example. The electronic component 70 may be a passive component or an active component. Specifically, any of the examples of the components usable for the electronic component 50 can be used as the electronic component 70.

An insulating layer 24 is provided at the bottom of the cavity 62. The insulating layer 24 may be formed mainly on the core layer 10 side than a lower surface of the electronic component 70. The insulating layer 24 covers the lower surface of the main body 71, side surfaces of the first electrodes 72, a side surface of the conductive bonding material 80, and a side surface of the metal layer 23 located on the pads 171, for example. The insulating layer 24 may be deposited to cover up to the side surfaces of the main body 71. An insulating layer 25 is provided on the insulating layer 24. The insulating layer 25 is deposited on the insulating layer 24 inside the cavity 62 to cover a portion of the electronic component 70 that is not covered with the insulating layer 24, and extends upward from the inside of the cavity 62 to cover the upper surface of the insulating layer 22. The insulating layer 25 covering the upper surface of the insulating layer 22 forms an interlayer insulator located between the interconnect layer 21 and the interconnect layer 26, together with the insulating layer 22. Materials used for and thicknesses of the insulating layers 24 and 25 may be the same as those of the insulating layer 14, for example. A resin having a high fluidity is preferably used as the material used for the insulating layer 24.

The interconnect layer 26 is formed on one side of the insulating layer 25. The interconnect layer 26 includes pads 26a and pads 26b formed on an upper surface of the insulating layer 25. The interconnect layer 26 may include interconnect patterns. The pads 26a are electrically connected to the interconnect layer 21 through via interconnects penetrating the insulating layers 25 and 22. The pads 26b are electrically connected to the second electrodes 73 of the electronic component 70 through via interconnects penetrating the insulating layer 25. A material used for the interconnect layer 26 and thicknesses of the pads 26a and the pads 26b may be the same as those of the interconnect layer 13, for example.

The solder resist layer 27 constitutes a protective insulating layer located at an outermost position on one side of the wiring board 1, and is formed on the upper surface of the insulating layer 25 to cover the interconnect layer 26. The solder resist layer 27 may be formed of a photosensitive epoxy-based insulating resin or a photosensitive acrylic-based insulating resin, for example. A thickness of the solder resist layer 27 is in a range of approximately 15 μm to approximately 35 μm, for example.

The solder resist layer 27 has openings 27x. The openings 27x penetrate the solder resist layer 27 and expose upper surfaces of the pads 26a and 26b of the interconnect layer 26. The pads 26a and 26b exposed inside the openings 27x can be used as pads to be electrically connected to a semiconductor device, for example. The surface of the interconnect layer 26 exposed inside the opening 27x may be covered with a metal layer similar to the metal layer 23, or may be coated with an organic film by performing an anti-oxidation process, such as an organic solderability preservative (OSP) process or the like.

In the illustrated example, the external connection terminals 28 protruding from an upper surface of the solder resist layer 27 are provided on the upper surfaces of the pads 26a and 26b exposed at the bottom of the openings 27x. The external connection terminals 28 have a structure in which a solder bump is formed on an upper surface of a copper post or the like, for example. An alloy including Pb, an alloy including Sn and Cu, an alloy including Sn and Ag, an alloy including Sn, Ag, and Cu, or the like can be used for the solder material, for example. The external connection terminals 28 can be used as terminals to be connected to a semiconductor chip. The external connection terminals 28 may be provided, as necessary. In a case where the external connection terminals 28 are not provided, the pads 26a and 26b exposed at the bottom of the openings 27x can be used as external connection terminals to be connected to the semiconductor chip.

The insulating layer 34 is formed on the lower surface 10b of the core layer 10 to cover the interconnect layer 33. A material used for and a thickness of the insulating layer 34 may be the same as those of the insulating layer 14, for example. The insulating layer 34 may include a filler, such as silica (SiO₂) or the like.

The interconnect layer 35 is formed on the other side of the insulating layer 34. The interconnect layer 35 includes via interconnects penetrating the insulating layer 34, and interconnect patterns and/or pads formed on the lower surface of the insulating layer 34. The interconnect pattern and/or the pad are electrically connected to the interconnect layer 33 through the via interconnect. The material of the interconnect layer 35 and the thickness of the interconnect pattern may be the same as those of the interconnect layer 13, for example.

The insulating layer 36 is formed on the lower surface of the insulating layer 34 to cover the interconnect layer 35. The material and thickness of the insulating layer 36 may be the same as those of the insulating layer 14, for example. The insulating layer 36 may include a filler, such as silica (SiO₂) or the like.

The interconnect layer 37 is formed on the other side of the insulating layer 36. The interconnect layer 37 includes via interconnects penetrating the insulating layer 36, and interconnect patterns and/or pads formed on a lower surface of the insulating layer 36. The interconnect patterns and/or the pads are electrically connected to the interconnect layer 35 through the via interconnects. A material used for the interconnect layer 37 and a thickness of the interconnect patterns or the like may be the same as those of the interconnect layer 13, for example.

The insulating layer 38 is formed on the lower surface of the insulating layer 36 to cover the interconnect layer 37. A material used for and a thickness of the insulating layer 38 may be the same as those of the insulating layer 14, for example. The insulating layer 38 may include a filler, such as silica (SiO₂) or the like.

The interconnect layer 39 is formed on the other side of the insulating layer 38. The interconnect layer 39 includes via interconnects penetrating the insulating layer 38, and interconnect patterns and/or pads formed on a lower surface of the insulating layer 38. The interconnect patterns and/or the pads are electrically connected to the interconnect layer 37 through the via interconnects. A material used for the interconnect layer 39 and a thickness of the interconnect patterns or the like may be the same as those of the interconnect layer 13, for example.

The insulating layer 40 is formed on the lower surface of the insulating layer 38 to cover the interconnect layer 39. A material used for and a thickness of the insulating layer 40 may be the same as those of the insulating layer 14, for example. The insulating layer 40 may include a filler, such as silica (SiO₂) or the like.

The interconnect layer 41 is formed on the other side of the insulating layer 40. The interconnect layer 41 includes via interconnects penetrating the insulating layer 40, and interconnect patterns and/or pads formed on a lower surface of the insulating layer 40. The interconnect patterns and/or the pads are electrically connected to the interconnect layer 39 through the via interconnects. A material used for the interconnect layer 41 and a thickness of the interconnect patterns or the like may be the same as those of the interconnect layer 13, for example.

The insulating layer 42 is formed on the lower surface of the insulating layer 40 to cover the interconnect layer 41. A material used for and a thickness of the insulating layer 42 may be the same as those of the insulating layer 14, for example. The insulating layer 42 may include a filler, such as silica (SiO₂) or the like.

The interconnect layer 46 is formed on the other side of the insulating layer 42. The interconnect layer 46 includes via interconnects penetrating the insulating layer 42, and interconnect patterns and/or pads formed on a lower surface of the insulating layer 42. The interconnect patterns and/or the pads are electrically connected to the interconnect layer 41 through the via interconnects. A material used for the interconnect layer 46 and a thickness of the interconnect patterns or the like may be the same as those of the interconnect layer 13, for example.

The solder resist layer 47 constitutes a protective insulating layer located at an outermost position on the other side of the wiring board 1, and is formed on the lower surface of the insulating layer 42 to cover the interconnect layer 46. A material used for and a thickness of the solder resist layer 47 may be the same as those of the solder resist layer 27, for example. The solder resist layer 47 includes openings 47x, and portions of the lower surface of the interconnect layer 46 are exposed inside the openings 47x. The planar shape of the openings 47x may be a circular shape, for example. The interconnect layer 46 exposed inside the openings 47x can be used as pads for electrical connection to a mounting substrate, such as a motherboard or the like. If necessary, the lower surface of the interconnect layer 46 exposed inside the openings 47x may be formed with the metal layer described above, or may be subjected to an anti-oxidation process, such as an OSP process or the like.

In the wiring board 1, the semiconductor chip can be connected to one or more external connection terminals 28. With the recent improved performances of semiconductor chips, it is becoming necessary to supply a larger amount of current so that the semiconductor chip can sufficiently exhibit a high performance. In the wiring board 1, it is effective to utilize the electronic component 70 disposed inside the cavity 62 to supply the larger amount of current to the semiconductor chip. In the wiring board 1, the electronic component 70 disposed inside the cavity 62 includes the first electrode 72 located on the lower surface of the electronic component 70 and the second electrode 73 located on the upper surface of the electronic component 70 and electrically connected to the first electrode 72. For this reason, the first electrode 72 can be electrically connected to the pad 171, and the second electrode 73 can be electrically connected to the external connection terminal 28. This makes it possible to supply a current from the side of the core layer 10 to the semiconductor chip mounted on the external connection terminal 28 via the pad 171 and the electronic component 70. As a result, it is possible to supply the current to the semiconductor chip more efficiently together with a current that is supplied to the semiconductor chip without passing through the electronic component 70.

### [Method for Manufacturing Wiring Board]

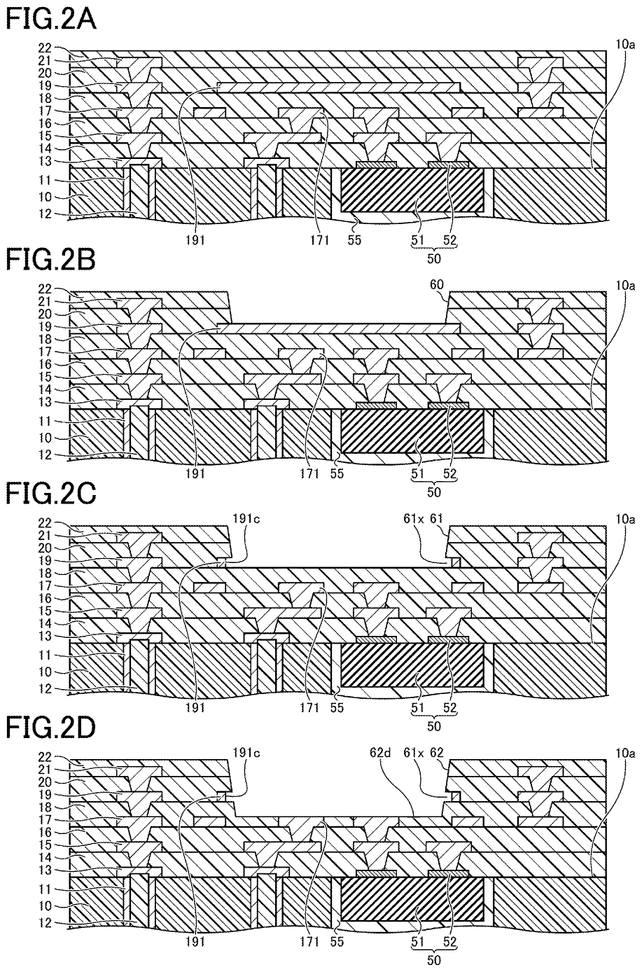

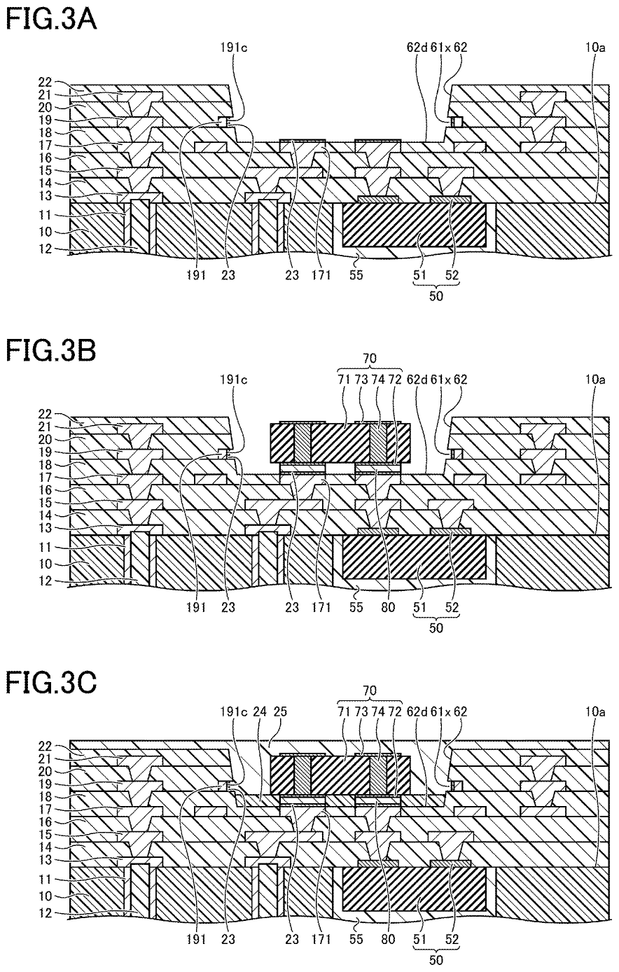

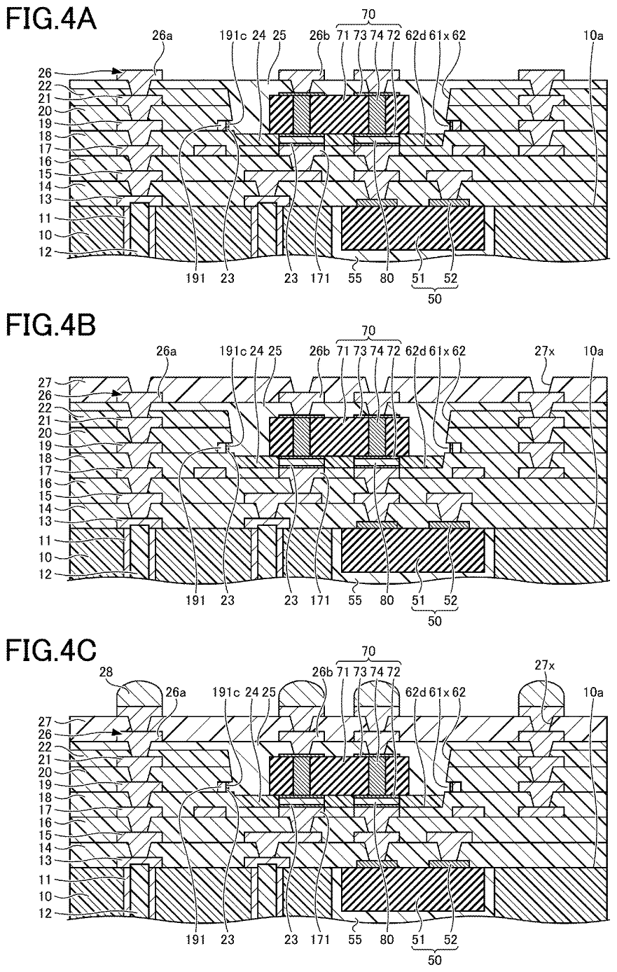

FIG. 2A, FIG. 2B, FIG. 2C, FIG. 2D, FIG. 3A, FIG. 3B, FIG. 3C, FIG. 4A, FIG. 4B, and FIG. 4C are diagrams illustrating examples of manufacturing processes of the wiring board according to the first embodiment, and illustrate portions of the cross section illustrated in FIG. 1. Because the upper surface 10a and the lower surface 10b of the core layer 10 are subjected to substantially the same processes, only the cross sections on the side of the upper surface 10a of the core layer 10 are illustrated and described in the following. Although the processes for manufacturing one wiring board are described below, the manufacturing processes may form multiple portions that become the wiring boards on a substrate and thereafter singulate the substrate into the portions of the individual wiring boards.

First, in the process (or step) illustrated in FIG. 2A, a stacked structure is prepared by sequentially stacking the interconnect layer 13, the insulating layer 14, the interconnect layer 15, the insulating layer 16, the interconnect layer 17, the insulating layer 18, the interconnect layer 19, the insulating layer 20, the interconnect layer 21, and the insulating layer 22 on the upper surface 10a of the core layer 10. The core layer 10 is embedded with the electronic component 50, and a periphery of the electronic component 50 is covered with the insulating resin 55. The core layer 10 includes the through-core vias 11 and the resin body 12. The interconnect layer 17 includes the pads 171, and the interconnect layer 19 includes the barrier interconnect 191 serving as the etching barrier.

The interconnect layers and the insulating layers illustrated in FIG. 2A may be formed using a known build-up method, for example. Specifically, the interconnect layers can be formed by various interconnect forming methods, such as a semi-additive method, a subtractive method, or the like, for example. The insulating layers can be formed by laminating and curing a semi-cured epoxy-based resin film or the like, for example. Instead of laminating the epoxy-based resin film or the like, a liquid or paste of the epoxy-based resin or the like may be coated and thereafter cured to form each insulating layer.

Next, in the process (or step) illustrated in FIG. 2B, a cavity 60 penetrating the insulating layers 20 and 22 and exposing the inner side of the upper surface of the barrier interconnect 191 is formed. Even after the cavity 60 is formed, the outer periphery of the barrier interconnect 191 is covered with the insulating layer 20. For example, when both the planar shape of the barrier interconnect 191 and the planar shape of the cavity 60 are rectangular shapes, the planar shape of the outer periphery of the barrier interconnect 191 covered with the insulating layer 20 is a rectangular picture-frame shape. A width of the outer periphery of the barrier interconnect 191 covered with the insulating layer 20 may be 50 μm or greater and 200 μm or less, for example. The cavity 60 can be formed by a laser processing method using a CO₂ laser or the like, for example. The inner surface of the cavity 60 may be perpendicular to the upper surface of the barrier interconnect 191, or may be inclined so that the width of the cavity 60 narrows toward the upper surface of the barrier interconnect 191.

Next, in the process (or step) illustrated in FIG. 2C, the barrier interconnect 191 exposed inside the cavity 60 is removed to deepen the cavity 60, that is, make the cavity 60 deeper. The cavity 60 after being deepened (that is, made deeper) will be referred to as a cavity 61. A portion of the barrier interconnect 191 covered with the insulating layer 20 is also removed, and a recess 61x having a picture-frame shape in the plan view is formed. The recess 61x has the bottom surface formed by the insulating layer 18, the top surface is formed by the insulating layer 20, and the side surface is formed by the inner surface 191c of the barrier interconnect 191. In the plan view, the barrier interconnect 191 having the picture-frame shape remains outside the recess 61x. The width of the bottom surface formed by the insulating layer 18 and the width of the top surface formed by the insulating layer 20 may be 15 μm or less, for example. In a case where the barrier interconnect 191 is made of copper (Cu), the barrier interconnect 191 can be removed by wet etching using a ferric chloride aqueous solution, a cupric chloride aqueous solution, an ammonium persulfate aqueous solution, or the like, for example.

Next, in the process (or step) illustrated in FIG. 2D, the insulating layer 18 exposed inside the cavity 61 illustrated in FIG. 2C is removed to deepen the cavity 61 and expose the upper surfaces of the pads 171. The cavity 61 that is extended toward the core layer 10 to expose the upper surface of the pad 171 will be referred to as the cavity 62. The bottom surface 62d of the cavity 62 is located inside the inner surface 191c of the barrier interconnect 191 in the plan view. The bottom surface 62d of the cavity 62 and the upper surfaces of the pads 171 lie on a single plane, for example. The insulating layer 18 may be removed by ashing, for example. Specifically, the insulating layer 18 can be removed by irradiating the upper surface of the insulating layer 18 exposed inside the cavity 61 illustrated in FIG. 2C with oxygen plasma in a high energy state, for example. After removing the insulating layer 18, a desmear process may be performed, as necessary, to remove residues of the insulating layer 18. During the ashing, a gas having a high etching capability, such as CF₄ plasma or the like, may be used.

Next, in the process (or step) illustrated in FIG. 3A, the metal layer 23 is formed on the inner surface 191c of the barrier interconnect 191 and the upper surfaces of the pads 171. A layer structure of the metal layer 23 is as described above. Each layer constituting the metal layer 23 can be formed by an electroless plating method, for example. This process of forming the metal layer 23 may be performed, as necessary.

Next, in the process (or step) illustrated in FIG. 3B, the electronic component 70 including the body 71, the first electrodes 72, the second electrodes 73, and the via interconnects 74 is prepared and mounted inside the cavity 62. Specifically, the first electrodes 72 of the electronic component 70 are bonded to the pads 171 by the conductive bonding material 80. Examples of the bonding material 80 are as described above.

Next, in the process (or step) illustrated in FIG. 3C, the insulating layers 24 and 25 are formed. First, a resin having a high fluidity is poured into the cavity 62 and cured to form the insulating layer 24 at the bottom of the cavity 60. The insulating layer 24 is mainly formed on the side closer to the core layer 10 than the lower surface of the electronic component 70. The insulating layer 24 may be deposited to cover the side surfaces of the main body 71 of the electronic component 70. Alternatively, the insulating layer 24 may be coated on the lower surface of the main body 71 in advance, and then filled into the cavity 62 when mounting components. Thereafter, the insulating layer 25 is deposited on top of the insulating layer 24 inside the cavity 62 to cover the electronic component 70, and to extend upward from within the cavity 62 to cover the upper surface of the insulating layer 22. Specifically, a semi-cured epoxy-based resin film or the like is laminated to cover the electronic component 70, and is cured to form the insulating layer 25, for example. Alternatively, instead of laminating the epoxy-based resin film or the like, a liquid or paste of the epoxy-based resin or the like may be coated and thereafter cured to form the insulating layer 25.

Next, in the process (or step) illustrated in FIG. 4A, the interconnect layer 26 is formed on the insulating layer 25. The interconnect layer 26 includes the pads 26a electrically connected to the interconnect layer 21, and the pads 26b electrically connected to the second electrodes 73 of the electronic component 70. The interconnect layer 26 may include interconnect patterns in addition to the pads 26a and 26b. When forming the pads 26a and 26b, via holes penetrating the insulating layers 22 and 25 and exposing the upper surface of the interconnect layer 21 and via holes penetrating the insulating layer 25 and exposing the upper surfaces of the second electrodes 73 of the electronic component 70 are first formed by a laser processing method or the like. Thereafter, the respective via holes can be filled by a semi-additive method or the like, to form the pads 26a and 26b extending on the upper surface of the insulating layer 25.

Next, in the process (or step) illustrated in FIG. 4B, the solder resist layer 27 is formed on the upper surface of the insulating layer 25 to cover the interconnect layer 26. The solder resist layer 27 may be formed by coating a liquid or paste of a photosensitive epoxy-based insulating resin or a photosensitive acrylic-based insulating resin on the upper surface of the insulating layer 25 by screen printing, roll coating, spin coating, or the like, for example, to cover the interconnect layer 26. Alternatively, the interconnect layer 26 may be formed by laminating a photosensitive epoxy-based insulating resin film or a photosensitive acrylic-based insulating resin film on the upper surface of the insulating layer 25, for example, to cover the interconnect layer 26. Next, the solder resist layer 27 is exposed and developed to form the openings 27x in the solder resist layer 27 to expose portions of the upper surfaces of the pads 26a and 26b of the interconnect layer 26.

Next, in the process (or step) illustrated in FIG. 4C, copper posts or the like are formed on the upper surfaces of the pads 26a and 26b exposed at the bottom of the openings 27x, and further, the external connection terminals 28 are formed by forming solder bumps on the upper surfaces of the copper posts or the like. An alloy including Pb, an alloy including Sn and Cu, an alloy including Sn and Ag, an alloy including Sn, Ag, and Cu, or the like can be used for the solder material, for example. The external connection terminals 28 can be formed by a semi-additive method, for example. The wiring board 1 is completed by the processes described above.

During the manufacturing processes of the wiring board 1, an outer periphery of the barrier interconnect 191 is covered with the insulating layer 20 when forming the cavity 60 in the process illustrated in FIG. 2B. For this reason, the cavity 60 is less likely to be affected by a processing error of each layer located above the barrier interconnect 191, and thus, the cavity 60 will not reach the outermost periphery of the barrier interconnect 191 and enable the processing in an appropriate range.

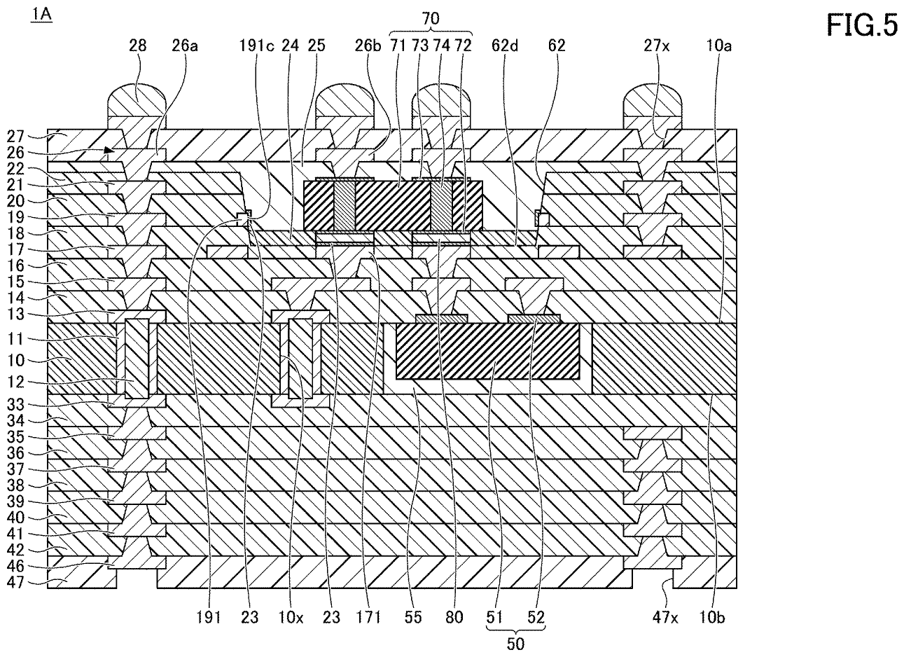

Further, because the barrier interconnect 191 is present in the process illustrated in FIG. 2C, the barrier interconnect 191 serves as a mask when the ashing is performed in the process illustrated in FIG. 2D, and the processing range below the barrier interconnect 191 is limited in a width direction of the cavity 62. For this reason, the bottom surface 62d of the cavity 62 can be located inside the inner surface 191c of the barrier interconnect 191 in the plan view. Although the cavity 62 is formed so as not to reach the barrier interconnect 191 in FIG. 2D, the cavity 62 may be formed so as to reach the barrier interconnect 191 by increasing an amount of ashing as illustrated in FIG. 5 which will be described later, for example. In this case, the bottom surface 62d of the cavity 62 can be located inside the inner surface 191c of the barrier interconnect 191 in the plan view. Accordingly, because the processing range below the barrier interconnect 191 is limited, the insulating layer that should not be removed can be prevented from being removed, and the interconnect that should be covered with the insulating layer can be prevented from being exposed inside the cavity. Hence, because the processing range below the barrier interconnect 191 is limited, and excessive etching of the insulating resin is less likely to occur. That is, it is possible to manufacture the wiring board 1 with reduced defects caused by misalignment when forming the cavity.

### <Modifications of First Embodiment>

In modifications of the first embodiment, an example of the wiring board having a structure different from that of the first embodiment will be described. In the modifications of the first embodiment, a description of constituent elements or components that are the same as those of the embodiment described above may be omitted.

FIG. 5 is a cross sectional view illustrating an example of the wiring board according to a first modification of the first embodiment. A wiring board 1A illustrated in FIG. 5 differs from the wiring board 1 in that the recess 61x is not provided.

In the wiring board 1A, an inner periphery of the upper surface of the barrier interconnect 191 is located inside the cavity 62, in addition to the inner surface 191c of the barrier interconnect 191. The outer periphery of the upper surface of the barrier interconnect 191 is covered with the insulating layer 20. Similar to the wiring board 1, the surfaces of the pads 171 and the barrier interconnect 191 located inside the cavity 62 may be covered with the metal layer 23. In the illustrated example, the upper surfaces of the pads 171, the inner surface 191c of the barrier interconnect 191, and the inner periphery of the upper surface of the barrier interconnect 191 are covered with the metal layer 23. The surfaces of the pads 171 and the barrier interconnect 191 located inside the cavity 62 do not necessarily have to be covered with the metal layer 23.

The manufacturing processes of the wiring board 1A are the same as the manufacturing processes of the wiring board 1, but the inner periphery of the upper surface of the barrier interconnect 191 can be positioned inside the cavity 62 by increasing the amount of ashing of the insulating layer 18 in the process illustrated in FIG. 2D. In this case, the barrier interconnect 191 also serves as a mask, and the processing range below the barrier interconnect 191 is limited in the width direction of the cavity 62, so that the bottom surface 62d of the cavity 62 can be located inside the inner surface 191c of the barrier interconnect 191 in the plan view. For this reason, it is possible to provide the wiring board 1A with reduced defects caused by misalignment when forming the cavity.

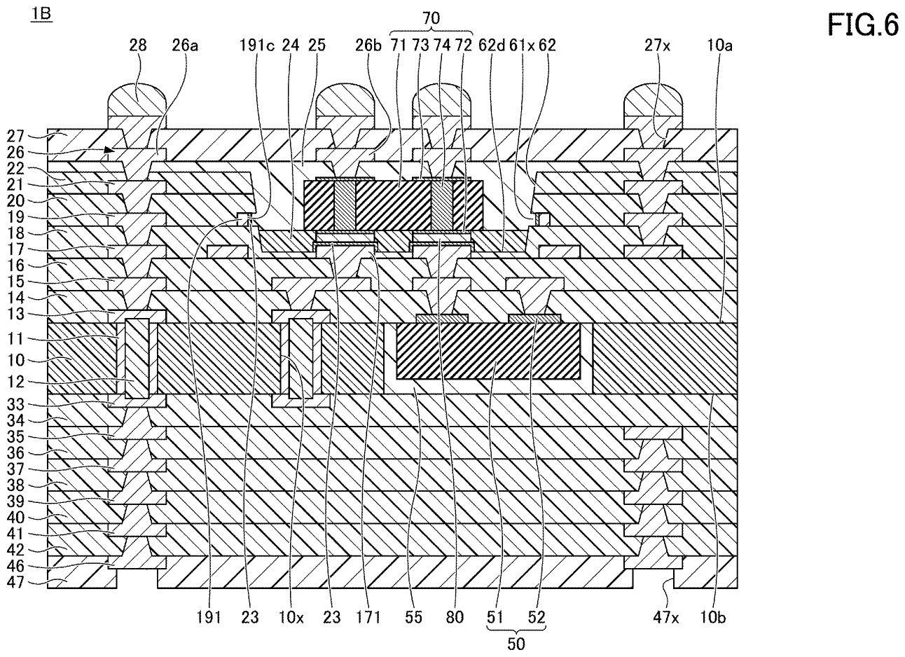

FIG. 6 is a cross sectional view illustrating an example of the wiring board according to a second modification of the first embodiment. The position of the bottom surface 62d of the cavity 62 in a wiring board 1B illustrated in FIG. 6 is different from that in the wiring board 1.

In the wiring board 1B, the bottom surface 62d of the cavity 62 is located closer to the core layer 10 than the upper surfaces of the pads 171. In other words, the upper surface of the pad 171 protrudes from the bottom surface 62d of the cavity 62, and a portion of the side surface of the pad 171 connected to the upper surface of the pad 171 is located inside the cavity 62. A portion of the side surface of the pad 171 is covered with the insulating layer 18. A height of the side surface of the pad 171 located inside the cavity 62 may be 1 μm or greater and 10 μm or less, for example. The upper surface and the side surface of the pad 171 located inside the cavity 62 may be covered with the metal layer 23.

The manufacturing processes of the wiring board 1B are the same as the manufacturing processes of the wiring board 1, but the bottom surface 62d of the cavity 62 can be made deeper by increasing the amount of ashing of the insulating layer 18 in the process illustrated in FIG. 2D. In this case, the barrier interconnect 191 also serves as a mask, and the processing range below the barrier interconnect 191 is limited in the width direction of the cavity 62, so that the bottom surface 62d of the cavity 62 can be located inside the inner surface 191c of the barrier interconnect 191 in the plan view. For this reason, it is possible to provide the wiring board 1B with reduced defects caused by misalignment when forming the cavity.

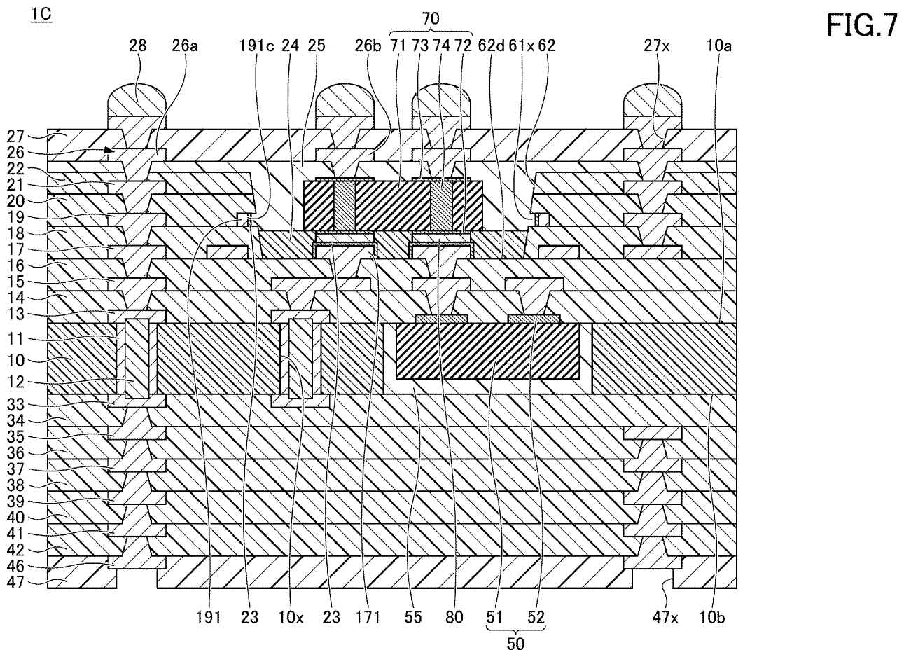

FIG. 7 is a cross sectional view illustrating an example of the wiring board according to a third modification of the first embodiment. In a wiring board 1C illustrated in FIG. 7, the position of the bottom surface 62d of the cavity 62 is deeper than that of the wiring board 1B.

In the wiring board 1C, the upper surface of the pad 171 protrudes from the bottom surface 62d of the cavity 62, and the upper and side surfaces of the pad 171 are located entirely inside the cavity 62. The lower surface of the pad 171 and the bottom surface 62d of the cavity 62 may lie on a single plane. The height of the side surface of the pad 171 located inside the cavity 62 (that is, the thickness of the pad 171) may be 10 μm or greater and 50 μm or less, for example. The upper and side surfaces of the pad 171 located inside the cavity 62 may be covered with the metal layer 23.

The manufacturing processes of the wiring board 1C are the same as the manufacturing processes of the wiring board 1B, but the bottom surface 62d of the cavity 62 can be made deeper by further increasing the amount of ashing of the insulating layer 18 in the process illustrated in FIG. 2D. In this case, the barrier interconnect 191 also serves as a mask, and the processing range below the barrier interconnect 191 is limited in the width direction of the cavity 62, so that the bottom surface 62d of the cavity 62 can be located inside the inner surface 191c of the barrier interconnect 191 in the plan view. For this reason, it is possible to manufacture the wiring board 1C with reduced defects caused by misalignment when forming the cavity.

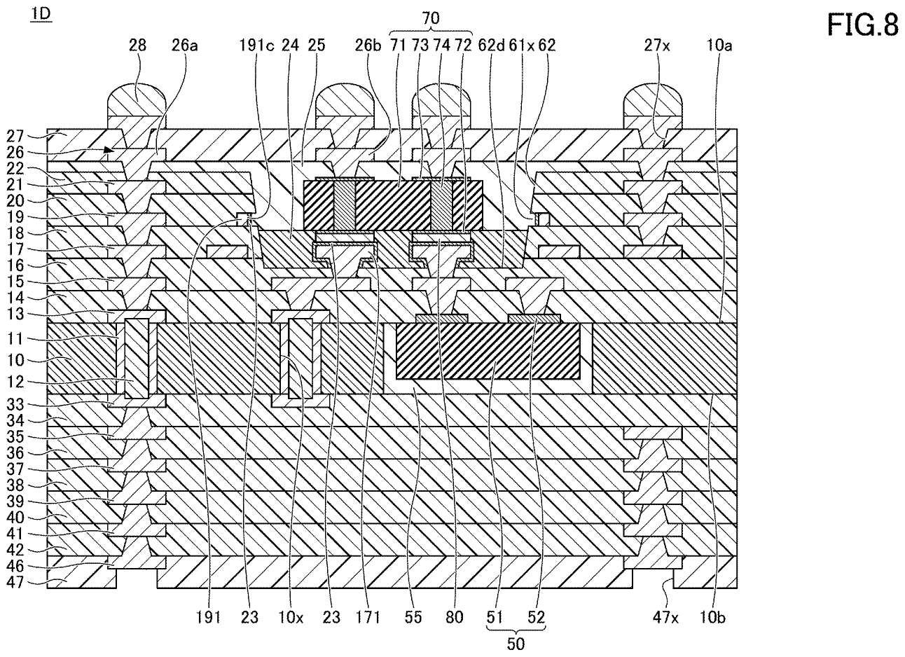

FIG. 8 is a cross sectional view illustrating an example of the wiring board according to a fourth modification of the first embodiment. In a wiring board 1D illustrated in FIG. 8, the position of the bottom surface 62d of the cavity 62 is even deeper than that of the wiring board 1C.

In the wiring board 1D, a portion of the via interconnect connected to the upper surface and the lower surface of the pad 171 protrudes from the bottom surface 62d of the cavity 62. The upper surface, the side surface, and the lower surface of the pad 171 and a portion of the side surface of the via interconnect connected to the lower surface of the pad 171 are located inside the cavity 62. The upper surface, the side surface, and the lower surface of the pad 171 located inside the cavity 62 and the side surface of the via interconnect connected to the lower surface of the pad 171 may be covered with the metal layer 23.

The manufacturing processes of the wiring board 1D are the same as the manufacturing processes of the wiring board 1C, but the bottom surface 62d of the cavity 62 can be made deeper by further increasing the amount of ashing of the insulating layer 18 in the process illustrated in FIG. 2D. In this case, the barrier interconnect 191 also serves as a mask, and the processing range below the barrier interconnect 191 is limited in the width direction of the cavity 62, so that the bottom surface 62d of the cavity 62 can be located inside the inner surface 191c of the barrier interconnect 191 in the plan view. For this reason, it is possible to provide the wiring board 1D with reduced defects caused by misalignment when forming the cavity.

### <Application Example of First Embodiment>

In an application example of the first embodiment, an example of a semiconductor device having a semiconductor chip mounted on the wiring board will be described. In the application example of the first embodiment, a description of constituent elements or components that are the same as those of the embodiment described above may be omitted.

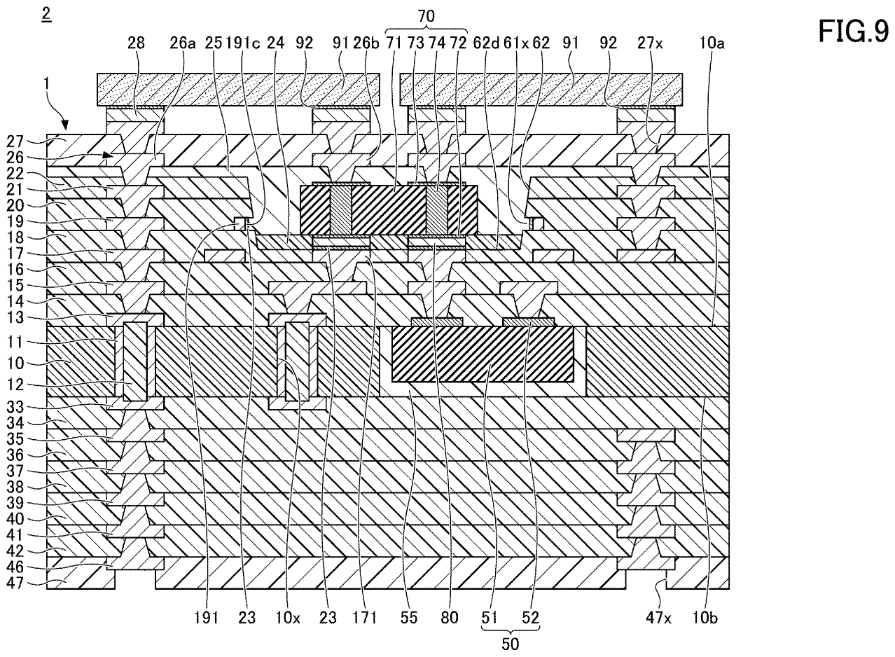

FIG. 9 is a cross sectional view illustrating an example of the semiconductor device according to the application example of the first embodiment. As illustrated in FIG. 9, a semiconductor device 2 includes the wiring board 1 illustrated in FIG. 1 and a semiconductor chip 91. The semiconductor chip 91 is mounted on the wiring board 1.

The semiconductor chip 91 includes a semiconductor integrated circuit (not illustrated) or the like formed on a thinned semiconductor substrate (not illustrated) made of silicon or the like, for example. Electrodes 92 electrically connected to the semiconductor integrated circuit (not illustrated) is formed on the semiconductor substrate (not illustrated). The electrodes 92 are connection terminals connected to the wiring board 1. The semiconductor chip 91 may include a processor, such as a central processing unit (CPU), a graphics processing unit (GPU), or the like, for example. The semiconductor chip 91 may include a memory, such as a high bandwidth memory (HBM), or the like, for example.

The electrode 92 of the semiconductor chip 91 is electrically connected to the pad 26a or 26b via the external connection terminal 28 of the wiring board 1. An underfill resin may be filled between the semiconductor chip 91 and the upper surface of the wiring board 1. In the illustrated example, two semiconductor chips 91 are mounted on the wiring board 1, but the number of semiconductor chips 91 mounted on the wiring board 1 may be one, or three or more.

As described above, the semiconductor device 2 can be provided by mounting the semiconductor chip 91 on the wiring board 1 according to the first embodiment. The wiring board 1 can be suitably used as an interposer board for high-speed data communication between the processor and the memory, for example. As described above, in the wiring board 1, a larger amount of current can be supplied to the semiconductor chip 91 mounted on the external connection terminals 28. For this reason, the semiconductor chip 91 can sufficiently exhibit a high performance.

Although the preferred embodiments are described above in detail, the present disclosure is not limited to the above described embodiments, and various variations, modifications, and substitutions can be made to the embodiments described above without departing from the scope of the present disclosure described in the claims.

For example, in the above embodiments, the wiring board in which the interconnect layer and the insulating layer are stacked on both surfaces of the core layer has been described. However, the present invention can be applied to a wiring board in which an interconnect layer and an insulating layer are stacked only on one surface side of a core layer, and the same effects are exhibited. The present invention is also applicable to a coreless substrate in which a core layer is omitted.

According to the disclosed technique, it is possible to provide a wiring board capable of reducing a defect caused by a positional deviation that occurs when forming a cavity in which an electronic component is to be disposed.

Various aspects of the subject-matter described herein may be set out non-exhaustively in the following numbered clauses:
1. A method for manufacturing a wiring board, comprising:
   preparing a structure including an interconnect layer including a pad, a first insulating layer formed on the interconnect layer, a barrier interconnect formed on the first insulating layer, and a second insulating layer formed on the first insulating layer and covering an upper surface of the barrier interconnect;
   forming a cavity penetrating the second insulating layer, coverings an outer periphery of an upper surface of the barrier interconnect, and exposing an inner periphery of the barrier interconnect;
   removing the barrier interconnect exposed inside the cavity to deepen the cavity; and
   removing the first insulating layer exposed inside the barrier interconnect to deepen the cavity and exposing an upper surface of the pad,
   wherein, during the exposing the upper surface of the pad, a bottom surface of the cavity is located inside an inner surface of the barrier interconnect in a plan view.
2. The method for manufacturing the wiring board according to clause 1, wherein:
   the forming the cavity forms the cavity by laser processing, and
   during the exposing the upper surface of the pad, the first insulating layer is removed by ashing using the barrier interconnect as a mask.

Although the modifications of the first embodiment are numbered with, for example, “first,” “second,” “third,” or “fourth,” the ordinal numbers do not imply priorities of the modifications. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A wiring board comprising:
an interconnect layer including a pad;
a first insulating layer formed on the interconnect layer;
a barrier interconnect formed on the first insulating layer and surrounding the pad in a plan view;
a second insulating layer formed on the first insulating layer and covering at least an outer periphery of an upper surface of the barrier interconnect; and
a cavity penetrating the second insulating layer and the first insulating layer and exposing an upper surface of the pad,
wherein a bottom surface of the cavity is located inside an inner surface of the barrier interconnect in the plan view.

2. The wiring board as claimed in claim 1, wherein the upper surface of the pad and at least a portion of a side surface of the pad are located inside the cavity.

3. The wiring board as claimed in claim 1, further comprising:
a via interconnect connected to a lower surface of the pad,
wherein a portion of a side surface of the via interconnect, the upper surface of the pad, and a side surface of the pad are located inside the cavity.

4. The wiring board as claimed in claim 1, wherein the inner surface of the barrier interconnect is located inside the cavity.

5. The wiring board as claimed in claim 1, wherein the cavity widens from a height position of the barrier interconnect.

6. The wiring board as claimed in claim 1, wherein surfaces of the pad and the barrier interconnect located inside the cavity are covered with a metal layer.

7. The wiring board as claimed in claim 1, further comprising:
an electronic component disposed inside the cavity, wherein:
the electronic component includes a first electrode located on a lower surface of the electronic component, and a second electrode located on an upper surface of the electronic component and electrically connected to the first electrode,
the first electrode is electrically connected to the pad, and
the second electrode is electrically connected to an external connection terminal.

8. The wiring board as claimed in claim 7, wherein the external connection terminal is a terminal to be connected to a semiconductor chip.

9. The wiring board as claimed in claim 1, wherein an inner periphery of the upper surface of the barrier interconnect is located inside the cavity, in addition to the inner surface of the barrier interconnect.

10. The wiring board as claimed in claim 1, wherein:
the upper surface of the pad protrudes from the bottom surface of the cavity,
a portion of a side surface of the pad connected to the upper surface of the pad is located inside the cavity, and
a portion of the side surface of the pad is covered with the first insulating layer.

11. The wiring board as claimed in claim 1, wherein:
the upper surface of the pad protrudes from the bottom surface of the cavity, and
the upper surface and a side surfaces of the pad are located entirely inside the cavity.

12. The wiring board as claimed in claim 11, wherein a lower surface of the pad and the bottom surface of the cavity lie on a single plane.

13. The wiring board as claimed in claim 1, wherein:
a portion of a via interconnect connected to the upper surface and a lower surface of the pad protrudes from the bottom surface of the cavity, and
the upper surface, a side surface, and the lower surface of the pad and a portion of a side surface of the via interconnect connected to the lower surface of the pad are located inside the cavity.
